(19) United States
(12) Patent Application Publication
(10) Pub. No.: US 2014/0054540 A1
(43) Pub. Date: Feb. 27, 2014

(54) DEVICE INCLUDING SEMICONDUCTOR NANOCRYSTALS & METHOD

(71) Applicant: QD Vision, Inc., Lexington, MA (US)

(72) Inventors: Zhaoqun Zhou, Allston, MA (US); Peter T. Kazlas, Sudbury, MA (US); Marshall Cox, North Haven, CT (US)

(73) Assignee: QD Vision, Inc., Lexington, MA (US)

(21) Appl. No.: 13/900,272

(22) Filed: May 22, 2013

Related U.S. Application Data
(63) Continuation of application No. PCT/US2011/052962, filed on Sep. 23, 2011.
(60) Provisional application No. 61/416,669, filed on Nov. 23, 2010.

(51) Int. Cl. H01L 29/06; H01L 33/06; H01L 33/00; H01L 31/0352; H01L 21/02; H01L 31/18

(52) U.S. Cl. CPC H01L 29/0665; H01L 21/02601; H01L 31/18; H01L 33/005; H01L 31/035218; H01L 33/06
USPC 257/9; 438/488; 438/97; 438/22

(57) ABSTRACT

A method of making a device comprising semiconductor nanocrystals comprises forming a first layer capable of transporting charge over a first electrode, wherein forming the first layer comprises disposing a metal layer over the first electrode and oxidizing at least the surface of the metal layer opposite the first electrode to form a metal oxide, disposing a layer comprising semiconductor nanocrystals over the oxidized metal surface, and disposing a second electrode over the layer comprising semiconductor nanocrystals. A device comprises a layer comprising semiconductor nanocrystals disposed between a first electrode and a second electrode, and a first layer capable of transporting charge disposed between the layer comprising semiconductor nanocrystals one of the electrodes, wherein the first layer capable of transporting charge comprises a metal layer wherein at least the surface of the metal layer facing the layer comprising semiconductor nanocrystals is oxidized prior to disposing semiconductor nanocrystals thereover.

This application is a continuation of International Application No. PCT/US2011/052962 filed 23 Sep. 2011, which was published in the English language as PCT Publication No. WO 2012/071107 on 31 May 2012, which International Application claims priority to U.S. Application No. 61/416,669 filed 23 Nov. 2010. Each of the foregoing is hereby incorporated herein by reference in its entirety.

### FEDERALLY SPONSORED RESEARCH OR DEVELOPMENT

This invention was made with Government support under SPAWAR Systems Center, San Diego (SSC SD) contract number N66001-07-C-2012 awarded by the Defense Advanced Research Project Agency (DARPA). The Government has certain rights in the invention.

### TECHNICAL FIELD OF THE INVENTION

This invention relates to the field of devices including semiconductor nanocrystals and related methods.

### SUMMARY OF THE INVENTION

In accordance with one aspect of the invention, there is provided a method of making a device that includes semiconductor nanocrystals. The method comprises forming a first layer capable of transporting charge over a first electrode, wherein forming the first layer comprises disposing a metal layer over the first electrode and oxidizing at least the surface of the metal layer opposite the first electrode to form a metal oxide, disposing a layer comprising semiconductor nanocrystals over the oxidized metal surface, and disposing a second electrode over the layer comprising semiconductor nanocrsytals.

In accordance with another aspect of the invention, there is provided a device including a layer comprising semiconductor nanocrystals disposed between a first electrode and a second electrode, and a first layer capable of transporting charge disposed between the layer comprising semiconductor nanocrystals one of the electrodes, wherein the first layer capable of transporting charge comprises a metal layer wherein at least the surface of the metal layer facing the layer comprising semiconductor nanocrystals is oxidized prior to disposing semiconductor nanocrystals thereover.

Preferably, the metal layer is oxidized in situ after the metal layer is included in the device structure.

In accordance with another aspect of the invention, there is provided a device including a layer comprising semiconductor nanocrystals disposed between a first electrode and a second electrode, and a first layer capable of transporting charge disposed between the layer comprising semiconductor nanocrystals one of the electrodes, wherein the first layer capable of transporting charge comprises a metal oxide having a conduction band that is approximately aligned with the work function of the proximate electrode.

In certain embodiments in which the metal oxide is proximate an electrode comprising a cathode, the metal oxide preferably comprises an n-type metal oxide. Preferred examples include but are not limited to bismuth oxide, zinc oxide, and titania. Mixtures of n-type metal oxides can also be used.

In certain embodiments, the device is made by a method described herein.

In certain other embodiments, the metal oxide can be prepared by sputtering, e-beam, or other known techniques.

In certain embodiments of the inventions described above and elsewhere herein, at least a portion of the semiconductor nanocrystals included in a device can generate an electrical output in response to absorption of light having a predetermined wavelength.

In certain embodiments of the inventions described above and elsewhere herein, at least a portion of the semiconductor nanocrystals included in the device emit light in response to photon or electrical excitation.

The foregoing, and other aspects and embodiments described herein and contemplated by this disclosure all constitute embodiments of the present invention.

It should be appreciated by those persons having ordinary skill in the art(s) to which the present invention relates that any of the features described herein in respect of any particular aspect and/or embodiment of the present invention can be combined with one or more of any of the other features of any other aspects and/or embodiments of the present invention described herein, with modifications as appropriate to ensure compatibility of the combinations. Such combinations are considered to be part of the present invention contemplated by this disclosure.

It is to be understood that both the foregoing general description and the following detailed description are exemplary and explanatory only and are not restrictive of the invention as claimed. Other embodiments will be apparent to those skilled in the art from consideration of the specification and practice of the invention disclosed herein.

### BRIEF DESCRIPTION OF THE DRAWINGS

In the drawings:

FIG. 1 illustrates a schematic drawing depicting a cross section of an example of an embodiment of the invention comprising a photodetector device.

FIG. 2 illustrates a schematic drawing depicting a cross section of an example of an embodiment of a device structure.

FIG. 3 depicts device architectures discussed in the Examples.

The attached figures are simplified representations presented for purposed of illustration only; the actual structures may differ in numerous respects, including, e.g., relative scale, etc.

For a better understanding to the present invention, together with other advantages and capabilities thereof, reference is made to the following disclosure and appended claims in connection with the above-described drawings.

### DETAILED DESCRIPTION OF THE INVENTION

In accordance with one aspect of the invention, there is provided a method of making a device comprising semiconductor nanocrystals. The method comprises forming a first layer capable of transporting charge over a first electrode, wherein forming the first layer comprises disposing a metal layer over the first electrode and oxidizing at least the surface of the metal layer opposite the first electrode to form a metal oxide, disposing a layer comprising semiconductor nanocrystals over the oxidized metal surface, and disposing a second electrode over the layer comprising semiconductor nanocrsytals.

Preferably, the entire surface of the first layer on which the layer comprising semiconductor nanocrystals is disposed is oxidized.

Preferably, the metal oxide is generated in situ by oxidation of at least a surface of metal layer after it is included in the device.

In accordance with another aspect of the invention, there is provided a device comprising a layer comprising semiconductor nanocrystals disposed between a first electrode and a second electrode, and a first layer capable of transporting charge disposed between the layer comprising semiconductor nanocrystals one of the electrodes, wherein the first layer capable of transporting charge comprises a metal layer wherein at least the surface of the metal layer facing the layer comprising semiconductor nanocrystals is oxidized prior to disposing semiconductor nanocrystals thereover.

Preferably, the first layer comprises a charge transport layer comprising a metal oxide that is generated in situ by oxidation of at least a surface of metal layer included in the device prior to disposing semiconductor nanocrystals thereover.

In the inventions described herein, the metal included in the metal layer can comprise an oxidizable metal. Example include, but are not limited to bismuth, zinc, aluminum, titanium, niobium, indium, tin, yttrium, ytterbium, copper, nickel, vanadium, chromium, gallium, manganese, magnesium, iron, cobalt, thallium, germanium, lead, zirconium, molybdenum, hafnium, tantalum, tungsten, cadmium, iridium, rhodium, ruthenium, osmium. Other oxidizable metals may be determined to be useful or desirable.

In certain embodiments, a metal comprises a metal which can provide an n-type metal oxide when oxidized.

In certain embodiments, a metal comprises a metal which can provide a p-type metal oxide when oxidized.

Optionally, the metal oxide formed can be further treated, e.g., doped, where the doping can comprise, for example, an oxygen deficiency, a halogen dopant, or a mixed metal. A dopant can be a p-type or an n-type dopant, depending upon the metal oxide and desired charge transport properties. For example, a hole transport material can include a p-type dopant, whereas an electron transport material can include an n-type dopant.

The metal layer can be deposited by known techniques. Examples include, but are not limited to, thermal evaporation of metal, vacuum deposition of metal, chemical vapor deposition, atomic layer deposition, etc.

In certain embodiments, the metal layer has a thickness of about 50 Angstroms to about 5 micrometers, such as a thickness in the range of 100 Angstroms to 100 nm, 100 nm to 1 micrometer, or 1 micrometer to 5 micrometers.

The metal layer can be oxidized by known techniques. A preferred technique comprises heating in air or other oxidizing atmosphere, e.g., but not limited to, baking in air or oxygen.

Preferably the metal layer is oxidized so as to at least form a layer of metal oxide that covers the top surface of the metal layer. Such layer can have a thickness from a monolayer of metal oxide to the total thickness of the metal layer.

In certain embodiments in which the total thickness of the metal layer is oxidized, the oxidized bottom surface of the layer can provide better attachment to an underlying layer, e.g., an ITO electrode layer. Such better attachment can benefit the mechanical properties of both the charge transport layer and the device.

In certain embodiments of the inventions described herein, for example, a device with photodetector capabilities, at least a portion of the semiconductor nanocrystals are selected to generate an electrical output in response to absorption of light having a predetermined wavelength, e.g., a wavelength in any one or more of the infrared, visible, ultraviolet, etc. regions of the spectrum.

In certain preferred embodiments, a device includes an inverted structure (e.g., the cathode is proximate to an electron transport layer).

In certain embodiments of the inventions described herein, e.g., a device with light emitting capabilities, at least a portion of the semiconductor nanocrystals are selected to emit light in response to photon or electrical excitation. Emitted light can have a peak emission wavelength in any one or more of the infrared, visible, ultraviolet, etc. regions of the spectrum. Semiconductor nanocrystals can be selected to provide emitted light including peak emission wavelength at one or more predetermined wavelengths.

In certain embodiments, a device can be configured to include both photodetector capabilities and light-emitting capabilities.

Inclusion of a charge transport material comprising a metal oxide can provide an advantage over organic charge transport materials due to the better chemical resistance of metal oxides to chemical treatments and other solution-processible device fabrication steps that may desirable.

Semiconductor nanocrystals can be disposed as a layer of semiconductor nanocrystals. A layer can be continuous or non-continuous.

Semiconductor nanocrystals can be arranged in a pattern or can be unpatterned. A pattern can optionally including repeating sub-patterns.

Depending on the type of device, semiconductor nanocrystals can be selected and arranged to detect or emit a plurality of different wavelengths or wavelength bands, e.g., from 1 to 100, from 1 to 10, from 3 to 10, different wavelengths or wavelength bands.

In one example of a detailed aspect of the invention, a device in accordance with the invention comprises two electrodes (e.g., anode and cathode) that can be supported by a substrate with layer of semiconductor nanocrystals disposed between the electrodes, and a charge transport layer between the layer comprising semiconductor nanocrystals and one of the electrodes, the charge transport layer comprising a metal layer at least a surface of which has been oxidized. Preferably the surface of the metal layer facing the layer comprising semiconductor nanocrystals is the oxidized surface.

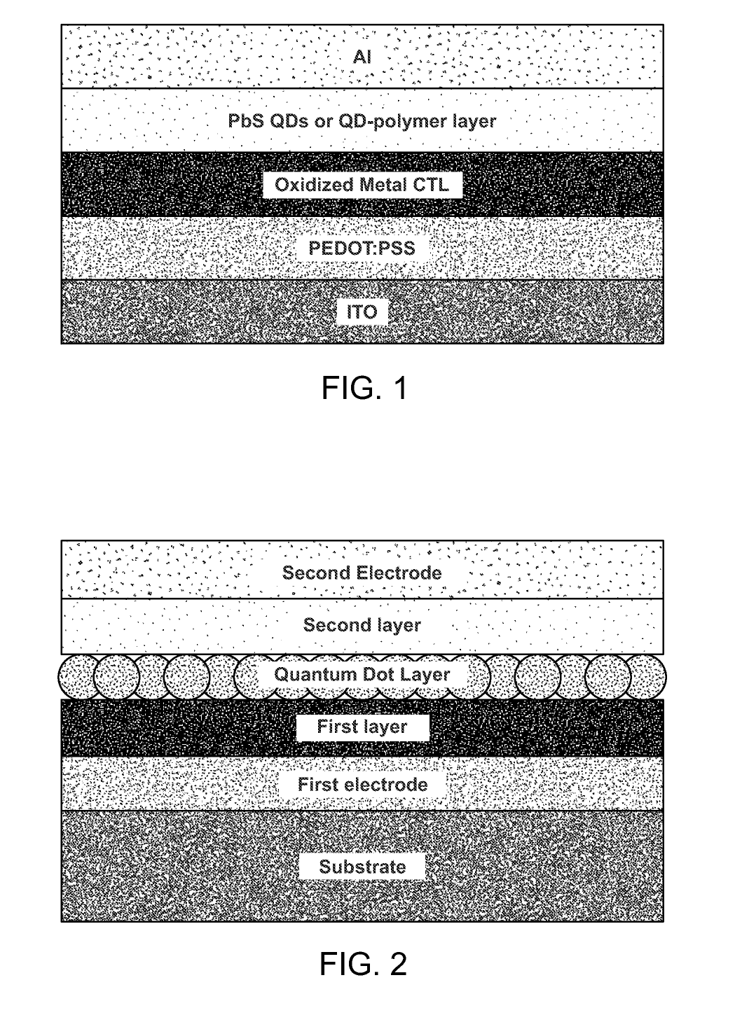

FIG. 1 illustrates a schematic drawing depicting a cross section of an example of an embodiment of a device in accordance with the present invention. The depicted example comprises a photodetector device. The example depicted in FIG. 1 includes semiconductor nanocrystals between the two electrodes and a charge transport layer comprising a metal layer at least a surface of which has been oxidized. As discussed herein, the semiconductor nanocrystals can be selected based upon the wavelength of electromagnetic radiation to be absorbed by the semiconductor nanocrystal when exposed thereto.

In a preferred embodiment, the semiconductor nanocrystals can be compacted, by for example, solution phase treatment with n-butyl amine after being deposited. See, for example, Oertel, et al., Appl. Phys. Lett. 87, 213505 (2005). See also Jarosz, et al., Phys. Rev. B 70, 195327 (2004); and Porter, et al., Phys. Rev. B 73 155303 (2006). Such compacting can increase the exciton dissociation efficiency and charge-transport properties of the deposited semiconductor nanocrystals.

In certain embodiments, a device can further include a second charge transport layer disposed between the layer of semiconductor nanocrystals and the second electrode.

In the example of the device structure depicted in FIG. 2, the structure includes a first electrode, a first layer capable of transporting charge comprising a metal layer at least a surface of which has been oxidized, a layer comprising semiconductor nanocrystals (referred to as “quantum dot layer” in FIGS. 1 and 2) disposed over the oxidized surface of the first layer; an optional second charge transport layer, and a second electrode.

The structure depicted in FIG. 2 may be fabricated as follows. A substrate having a first electrode (e.g., an anode (for example, PEDOT); the first electrode can alternatively comprise a cathode) disposed thereon may be obtained or fabricated using any suitable technique. The first electrode may optionally be patterned. A layer comprising a metal is deposited over the first electrode using any suitable technique. At least the upper surface of the metal layer is oxidized. Optionally, the metal layer can oxidized through the thickness of the layer in addition to the top surface. A layer comprising semiconductor nanocrystals can be deposited by techniques known or readily identified by one skilled in the relevant art. An optional second layer capable of transporting charge is disposed over the layer comprising quantum dots. Such second layer can be deposited using any suitable technique. A second electrode may be deposited using any suitable technique.

Alternatively, the structure of device structures depicted in FIGS. 1 and 2 can be inverted.

If the example of the device structure shown in FIG. 2 is to function as a photodetector, the electromagnetic radiation to be absorbed can pass through the bottom of the structure. If an adequately light transmissive top electrode is used, the structure could also absorb electromagnetic radiation through the top of the structure.

If the example of the device structure shown in FIG. 2 is to function as a light-emitting device, the electromagnetic radiation to be emitted can pass through the bottom of the structure. If an adequately light transmissive top electrode is used, the structure could also emit electromagnetic radiation through the top of the structure.

The simple layered structures illustrated in FIGS. 1 and 2 are provided by way of non-limiting example, and it is understood that embodiments of the invention may be used in connection with a wide variety of other structures. The specific materials and structures described herein are exemplary in nature, and other materials and structures may be used.

Devices may be achieved by combining the various layers described in different ways, or layers may be omitted entirely, based on design, performance, and cost factors. Other layers not specifically described may also be included. Materials other than those specifically described may be used. Optionally, one or more of the layers can be patterned. For example, patterned layers comprising electrode material or a charge transport material can be deposited by vapor deposition using shadow masks or other masking techniques.

Optionally, a protective glass layer can be used to encapsulate the device. Optionally a desiccant or other moisture absorptive material can be included in the device before it is sealed, e.g., with an epoxy, such as a UV curable epoxy. Other desiccants or moisture absorptive materials can be used.

The substrate can be opaque or transparent. An example of a suitable substrate includes a transparent substrate such as those used in the manufacture of a transparent light emitting device. See, for example, Bulovic, V. et al., Nature 1996, 380, 29; and Gu, G. et al., Appl. Phys. Lett. 1996, 68, 2606-2608, each of which is incorporated by reference in its entirety. The substrate can comprise plastic, metal, glass, or a semiconductor material (e.g., silicon, silicon carbide, germanium, etc.). The substrate can be rigid or flexible.

The substrate can have direct or indirect integration to electronics.

In certain embodiments of devices comprising photodetectors, the substrate can include preamplifiers integrated to the semiconductor nanocrystals. For example, preamplifiers can be configured to individual pixel-detector elements.

The first electrode can be, for example, a high work function conductor capable of conducting holes, e.g., comprising a hole-injecting or hole-receiving conductor, such as an indium tin oxide (ITO) layer. Other first electrode materials can include gallium indium tin oxide, zinc indium tin oxide, titanium nitride, or polyaniline. The second electrode can be, for example, a low work function (e.g., less than 4.0 eV) conductor capable of conducting electrons, e.g., comprising an electron-injecting or electron-receiving material, e.g., a metal, such as Al, Ba, Yb, Ca, a lithium-aluminum alloy (Li:Al), or a magnesium-silver alloy (Mg:Ag). The first electrode can have a thickness of about 500 Angstroms to 4000 Angstroms. The second electrode can have a thickness of about 50 Angstroms to greater than about 1000 Angstroms.

In a device comprising a photodetector, preferably, at least one electrode is at least partially light-transmissive, and more preferably transparent, to the one or more wavelengths to be detected by the semiconductor nanocrystals included in the device. In embodiments for detecting more than one wavelength, the device includes semiconductor nanocrystals selected to absorb each of the wavelengths to be detected.

In a device comprising a light emitting device, preferably, at least one electrode is at least partially light-transmissive, and more preferably transparent, to the one or more wavelengths to be emitted by the semiconductor nanocrystals included in the device. In embodiments for emitting more than one wavelength, the device includes semiconductor nanocrystals selected to emit each of the wavelengths to be emitted.

Preferably, at least one surface of the device is light-transmissive. For example, if the substrate of the display is opaque, a material that is transmissive to light is preferably used for forming the top electrode of the device. Examples of electrode materials useful for forming an electrode that can at least partially transmit light in the visible region in the spectrum include conducting polymers, indium tin oxide (ITO) and other metal oxides, low or high work function metals, or conducting epoxy resins that are at least partially light transmissive. When a transparent electrode is desired, the electrode preferably is formed from a thin layer of electrode material, e.g., high work function metal, of a thickness that is adequately transparent and conductive. An example of a conducting polymer that can be used as an electrode material is poly(ethlyendioxythiophene), sold by Bayer AG under the trade mark PEDOT. Other molecularly altered poly(thiophenes) are also conducting and could be used, as well as emaraldine salt form of polyaniline.

As discussed above, a device can further include a second charge transport layer.

A charge transport layer for use in the second charge transport layer can comprise a material capable of transporting holes or a material capable of transporting electrons. In embodiments of the device which include a first charge transport layer and a second transport layer, preferably one of the transport layers comprises a material capable of transporting holes and the other comprises a material capable of transporting electrons. More preferably, the charge transport layer comprising a material capable of transporting holes is proximate to the electrode comprising a high work function hole-injecting or hole—receiving conductor and the charge transport layer comprising a material capable of transporting electrons is proximate to the electrode comprising a low work function electron-injecting or electron-receiving conductor. For example, in reverse biased device embodiments including an HTL, the HTL transports holes from the semiconductor nanocrystals to the anode.

In certain embodiments, semiconductor nanocrystals can be included in a host material.

In certain embodiments, a host material can comprise a material capable of transporting charge.

In certain embodiments, semiconductor nanocrystals can be included in a layer comprising a material capable of transporting charge (e.g., holes or electrons).

Other host materials in which semiconductor nanocrsytals can be includes are discussed elsewhere herein.

In certain embodiments, semiconductor nanocrsytals are not included in a host material and are disposed as a separate layer.

In certain embodiments, a first charge transport layer can have a thickness of about 50 Angstroms to about 5 micrometers, such as a thickness in the range of 100 Angstroms to 100 nm, 100 nm to 1 micrometer, or 1 micrometer to 5 micrometers. Other thickness may be determined to be useful or desirable.

An optional second charge transport layer can have a thickness of about 50 Angstroms to about 5 micrometers, such as a thickness in the range of 100 Angstroms to 100 nm, 100 nm to 1 micrometer, or 1 micrometer to 5 micrometers. Other thickness may be determined to be useful or desirable.

A second charge transport layer (e.g., a hole transport layer (HTL) or an electron transport layer (ETL)) can include an inorganic material or an organic material.

Examples of inorganic material include, for example, inorganic semiconductors. The inorganic material can be amorphous or polycrystalline.

An organic charge transport material can be polymeric or non-polymeric.

An example of a typical organic material that can be included in an electron transport layer includes a molecular matrix. The molecular matrix can be non-polymeric. The molecular matrix can include a small molecule, for example, a metal complex. For example, the metal complex of 8-hydroryquinoline can be an aluminum, gallium, indium, zinc or magnesium complex, for example, aluminum tris(8-hydroxyquinoline) (Alq₃). In certain embodiments, the electron transport material can comprise LT-N820 available from Luminescent Technologies, Taiwan. Other classes of materials in the electron transport layer can include metal thioxinoid compounds, oxadiazole metal chelates, triazoles, sexithiophenes derivatives, pyrazine, and styrylanthracene derivatives. An electron transport layer comprising an organic material may be intrinsic (undoped) or doped. Doping may be used to enhance conductivity. See, for example, U.S. Provisional Patent Application No. 60/795,420 of Beatty et al., for “Device Including Semiconductor Nanocrystals And A Layer Including A Doped Organic Material And Methods”, filed 27 Apr. 2006, which is hereby incorporated herein by reference in its entirety.

An examples of a typical organic material that can be included in a hole transport layer includes an organic chromophore. The organic chromophore can include a phenyl amine, such as, for example, N,N′-diphenyl-N,N′-bis(3-methylphenyl)-(1,1′-biphenyl)-4,4′-diamine (TPD). Other hole transport layer can include spiro-TPD, 4-4′-N,N′-dicarbazolyl-biphenyl (CBP), 4,4-. bis[N-(1-naphthyl)-N-phenylamino]biphenyl (NPD), etc., a polyaniline, a polypyrrole, a poly(phenylene vinylene), copper phthalocyanine, an aromatic tertiary amine or polynuclear aromatic tertiary amine, a 4,4′-bis(p-carbazolyl)-1,1′-biphenyl compound, or an N,N,N′,N′-tetraarylbenzidine. A hole transport layer comprising an organic material may be intrinsic (undoped) or doped. Doping may be used to enhance conductivity. Examples of doped hole transport layers are described in U.S. Provisional Patent Application No. 60/795,420 of Beatty et al., for “Device Including Semiconductor Nanocrystals And A Layer Including A Doped Organic Material And Methods”, filed 27 Apr. 2006, which is hereby incorporated herein by reference in its entirety.

Organic charge transport layers may be disposed by known methods such as a vacuum vapor deposition method, a sputtering method, a dip-coating method, a spin-coating method, a casting method, a bar-coating method, a roll-coating method, and other film deposition methods. Preferably, organic layers are deposited under ultra-high vacuum (e.g., ≦10⁻⁸ torr), high vacuum (e.g., from about 10⁻⁸ ton to about 10⁻⁵ ton), or low vacuum conditions (e.g., from about 10⁻⁵ ton to about 10⁻³ ton). Most preferably, the organic layers are deposited at high vacuum conditions of from about 1×10⁻⁷ to about 5×10⁻⁶ torr. Alternatively, organic layers may be formed by multi-layer coating while appropriately selecting solvent for each layer.

Charge transport layers comprising an inorganic semiconductor can be deposited on a substrate at a low temperature, for example, by a known method, such as a vacuum vapor deposition method, an ion-plating method, sputtering, inkjet printing, etc.

For examples of HTL and ETL materials, see U.S. patent application Ser. No. 11/354,185 of Bawendi et al., entitled “Light Emitting Devices Including Semiconductor Nanocrystals”, filed 15 Feb. 2006 (U.S. Publication No. 2007-0103068), and U.S. patent application Ser. No. 11/253,595 of Coe-Sullivan et al., entitled “Light Emitting Device Including Semiconductor Nanocrystals”, filed 21 Oct. 2005 (U.S. Publication No. 2008-000167), and U.S. patent application Ser. No. 10/638,546 of Kim et al., entitled “Semiconductor Nanocrystal Heterostructures”, filed 12 Aug. 2003 (now U.S. Pat. No. 7,390,568), each of which is hereby incorporated by reference herein in its entirety.

Optionally, one or more additional layers can be included between the two electrodes.

Each layer included in the device may optionally comprise one or more layers.

In certain embodiments, a device includes a layer comprising a pattern of features comprising semiconductor nanociystals with tunable spectral properties selected based on the desired light-absorption or light-emissive properties therefor.

As disused above, in a device comprising a photodetector device, semiconductor nanociystals can generate an electrical response or output in response to absorption of light at the wavelength to be detected. For example, upon absorption of the light to be detected, e.g., IR, MIR, a particular visible wavelength, etc., by a semiconductor nanocrystal, a hole and electron pair are generated. The hole and electron are separated by, e.g., application of voltage, before they pair combine in order to generate an electrical response to be recorded. For example, the wavelength of the detected light or radiation can be between 300 and 2,500 nm or greater, for instance between 300 and 400 nm, between 400 and 700 nm, between 700 and 1100 nm, between 1100 and 2500 nm, or greater than 2500 nm. In certain embodiments, detection capability in the range from 1000 nm to 1800 nm, or 1100 nm to 1700 nm, is preferred.

As discussed above, in a device comprising a light emitting device, semiconductor nanocrystals can emit light at a predetermined wavelength. For example, upon optical or electrical excitation, a photon of light having a particular wavelength, etc., can be emitted by a semiconductor nanocrystal. For example, the wavelength of the emitted light can be in any one or more of the infrared, visible, ultraviolet, etc. regions of the spectrum.

Semiconductor nanocrystals comprise nanometer—scale inorganic semiconductor particles. Semiconductor nanocrystals preferably have an average nanocrystal diameter less than about 150 Angstroms (Å), and more preferably in the range of 12-150 Å. Most preferably the semiconductor nanocrystals have an average nanocrystal diameter in a range from about 2 nm to about 10 nm.

In certain embodiments, semiconductor nanocrystals comprise Group II-VI compounds, Group II-V compounds, Group III-VI compounds, Group III-V compounds, Group IV-VI compounds, Group compounds, Group II-IV-VI compounds, or Group II-IV-V compounds, and/or mixtures and/or alloys thereof, including ternary and quaternary mixtures and/or alloys. Examples include, but are not limited to, ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbS, PbSe, PbTe, and/or mixtures and/or alloys thereof, including ternary and quaternary mixtures and/or alloys. In certain embodiments, semiconductor nanocrystals comprise Group IV elements.

Semiconductor nanocrystals can have effective band gaps that range from the near UV to the infrared, from ˜350 nm to ˜3.0 micron.

In certain embodiments for detecting infrared wavelength radiation, semiconductor nanocrystals comprising PbS, PbSe, InSb, or InAs are preferred. In certain embodiments for detecting visible wavelength radiation, semiconductor nanocrystals comprising Group II-V Compounds and/or mixtures and/or alloys thereof, including ternary and quaternary mixtures are preferred.

In certain embodiments, semiconductor nanocrystals include a “core” of one or more first semiconductor materials, which may be surrounded by an overcoating or “shell” of a second semiconductor material. A semiconductor nanocrystal core surrounded by a semiconductor shell is also referred to as a “core/shell” semiconductor nanocrystal.

For example, the semiconductor nanocrystal can include a core having the formula MX, where M is cadmium, zinc, magnesium, mercury, aluminum, gallium, indium, thallium, or mixtures thereof, and X is oxygen, sulfur, selenium, tellurium, nitrogen, phosphorus, arsenic, antimony, or mixtures thereof. Examples of materials suitable for use as semiconductor nanocrystal cores include, but are not limited to, CdS, CdO, CdSe, CdTe, ZnS, ZnO, ZnSe, ZnTe, MgTe, GaAs, GaP, GaSb, GaN, HgS, HgO, HgSe, HgTe, InAs, InP, InSb, InN, AlAs, AlP, AlSb, AlS, PbS, PbO, PbSe, Ge, Si, alloys thereof, and/or mixtures thereof, including ternary and quaternary mixtures and/or alloys. Examples of materials suitable for use as semiconductor nanocrystal shells include, but are not limited to, CdS, CdO, CdSe, CdTe, ZnS, ZnO, ZnSe, ZnTe, MgTe, GaAs, GaP, GaSb, GaN, HgS, HgO, HgSe, HgTe, InAs, InP, InSb, InN, AlAs, AlP, AlSb, AlS, PbS, PbO, PbSe, Ge, Si, alloys thereof, and/or mixtures thereof, including ternary and quaternary mixtures and/or alloys.

In certain embodiments, the surrounding “shell” material has a bandgap greater than the bandgap of the core material. In certain embodiments, the shell is chosen so as to have an atomic spacing close to that of the “core” substrate. In certain embodiments, the surrounding shell material has a bandgap less than the bandgap of the core material. In a further embodiment, the shell and core materials can have the same crystal structure.

For further examples of core/shell semiconductor structures, see U.S. application Ser. No. 10/638,546, entitled “Semiconductor Nanocrystal Heterostructures”, filed 12 Aug. 2003 (now U.S. Pat. No. 7,390,568), which is hereby incorporated herein by reference in its entirety.

The semiconductor nanocrystals are members of a population of semiconductor nanocrystals having a size distribution. In certain embodiments, semiconductor nanocrystals comprise a monodisperse or substantially monodisperse population of semiconductor nanocrystals. The monodisperse distribution of diameters can also be referred to as a size. Optionally, the monodisperse population of the semiconductor nanocrystals comprising a particular structure and composition can exhibit less than a 15% rms deviation in the size of the nanocrystals, or less than 10%, or less than 5%.

Preparation and manipulation of semiconductor nanocrystals are described, for example, in U.S. Pat. Nos. 6,322,901 and 6,576,291, and U.S. Patent Application No. 60/550,314, each of which is hereby incorporated herein by reference in its entirety. Additional examples of methods of preparing semiconductor nanocrystal are described in U.S. patent application Ser. No. 11/354,185 of Bawendi et al., entitled “Light Emitting Devices Including Semiconductor Nanocrystals”, filed 15 Feb. 2006 (U.S. Publication No. 2007-0103068); U.S. patent application Ser. No. 11/253,595 of Coe-Sullivan et al., entitled “Light Emitting Device Including Semiconductor Nanociystals”, filed 21 Oct. 2005 (U.S. Publication No. 2008-000167); U.S. patent application Ser. No. 10/638,546 of Kim et al., entitled “Semiconductor Nanocrystal Heterostructures”, filed 12 Aug. 2003 (now U.S. Pat. No. 7,390,568), referred to above; Murray, et al., J. Am. Chem., Soc., Vol. 115, 8706 (1993); Kortan, et al., J. Am. Chem. Soc., Vol. 112, 1327 (1990); and the Thesis of Christopher Murray, “Synthesis and Characterization of II-VI Quantum Dots and Their Assembly into 3-D Quantum Dot Superlattices”, Massachusetts Institute of Technology, September, 1995. Each of the foregoing is hereby incorporated by reference herein in its entirety.

The semiconductor nanocrystals optionally have ligands attached thereto.

In certain embodiments, the ligands can be derived from a coordinating solvent used during the growth process. The surface can be modified by repeated exposure to an excess of a competing coordinating group to form an overlayer. For example, a dispersion of the capped semiconductor nanocrystal can be treated with a coordinating organic compound, such as pyridine, to produce crystallites which disperse readily in pyridine, methanol, and aromatics but no longer disperse in aliphatic solvents. Such a surface exchange process can be carried out with any compound capable of coordinating to or bonding with the outer surface of the semiconductor nanocrystal, including, for example, phosphines, thiols, amines and phosphates. The semiconductor nanocrystal can be exposed to short chain polymers which exhibit an affinity for the surface and which terminate in a moiety having an affinity for a suspension or dispersion medium. Such affinity improves the stability of the suspension and discourages flocculation of the semiconductor nanocrystal. In other embodiments, semiconductor nanocrystals can alternatively be prepared with use of non-coordinating solvent(s).

A suitable coordinating ligand can be purchased commercially or prepared by ordinary synthetic organic techniques, for example, as described in J. March, Advanced Organic Chemistry, which is incorporated herein by reference in its entirety. See also U.S. patent application Ser. No. 10/641,292 entitled “Stabilized Semiconductor Nanocrystals”, filed 15 Aug. 2003 (now U.S. Pat. No. 7,160,613), which is hereby incorporated herein by reference in its entirety. See also the patent applications, which include descriptions of preparation methods, that are listed above.

Other examples of ligands include benzylphosphonic acid, benzylphosphonic acid including at least one substituent group on the ring of the benzyl group, a conjugate base of such acids, and mixtures including one or more of the foregoing. In certain embodiments, a ligand comprises 4-hydroxybenzylphosphonic acid, a conjugate base of the acid, or a mixture of the foregoing. In certain embodiments, a ligand comprises 3,5-di-tert-butyl-4-hydroxybenzylphosphonic acid, a conjugate base of the acid, or a mixture of the foregoing.

Additional examples of ligands that may be useful with the present invention are described in International Application No. PCT/US2008/010651, filed 12 Sep. 2008, of Breen, et al., for “Functionalized Nanoparticles And Method” and International Application No. PCT/US2009/004345, filed 28 Jul. 2009 of Breen et al., for “Nanoparticle Including Multi-Functional Ligand And Method”, each of the foregoing being hereby incorporated herein by reference.

Semiconductor nanocrystals can have various shapes, including sphere, rod, disk, other shapes, and mixtures of various shaped particles.

Semiconductor nanocrystals can achieve high absorption cross-section per unit thickness.

In addition to their potential for increased sensitivity and increased operating temperature, semiconductor nanocrystals provide the advantage of a tunable range of wavelength sensitivities.

As discussed above, by selection of the composition and controlling size, semiconductor nanocrystals can be tuned through a wide range of optical band gaps. For example, PbSe semiconductor nanocrystals can be tuned from 1.1 μm to 2.2 μm just by changing the size of the particle. Changing the semiconductor material permits coarse adjustment of the band gap of the material, enabling materials capable of absorbing in the ultraviolet, visible, near-infrared, and mid-infrared regions of the spectrum.

In fabricating certain embodiments of the device including second charge transport layer, the second layer is preferably deposited via physical vapor deposition. The sandwich structure of this embodiment is similar to that of a p-i-n diode.

In certain embodiments, semiconductor nanocrystals can be deposited using contact printing. See, for example, A. Kumar and G. Whitesides, Applied Physics Letters, 63, 2002-2004, (1993); and V. Santhanam and R. P. Andres, Nano Letters, 4, 41-44, (2004), each of which is incorporated by reference in its entirety. See also U.S. patent application Ser. No. 11/253,612, filed 21 Oct. 2005, entitled “Method And System For Transferring A Patterned Material”, of Coe-Sullivan et al. (U.S. Publication No. 2006-0196375) and U.S. patent application Ser. No. 11/253,595, filed 21 Oct. 2005, entitled “Light Emitting Device Including Semiconductor Nanocrystals,” of Coe-Sullivan, et al. (U.S. Publication No. 2008-000167), each of which is incorporated herein by reference in its entirety.

Contact printing provides a method for applying a material to a predefined region on a substrate. The predefined region is a region on the substrate where the material is selectively applied. The material and substrate can be chosen such that the material remains substantially entirely within the predetermined area. By selecting a predefined region that forms a pattern, material can be applied to the substrate such that the material forms a pattern. The pattern can be a regular pattern (such as an array, or a series of lines), or an irregular pattern. Once a pattern of material is formed on the substrate, the substrate can have a region including the material (the predefined region) and a region substantially free of material. In some circumstances, the material forms a monolayer on the substrate. The predefined region can be a discontinuous region. In other words, when the material is applied to the predefined region of the substrate, locations including the material can be separated by other locations that are substantially free of the material.

A layer including semiconductor nanocrsytals can have various thickness, e.g., from a monolayer thickness to a predetermined thickness.

Contact printing optionally allows a substantially dry (i.e., substantially liquid or solvent free) application of a patterned semiconductor nanocrystal film to a surface, thus freeing the surface of solubility and surface chemistry requirements.

Semiconductor nanocrystals can alternatively be deposited by solution based processing techniques, silk-screening, inkjet printing, and other liquid film techniques available for forming patterns on a surface.

Liquid based deposition techniques utilize one or more colloidal dispersions including the semiconductor nanocrystals to be included in the device. Such deposition method facilitates forming a layer comprising semiconductor nanocrystals, which can be patterned or unpatterned.

In certain embodiments, semiconductor nanocrystals comprise semiconductor nanocrystals dispersed in a host material (e.g., a polymer, a resin, a silica glass, silica gel, aerogel, other porous or nonporous matrices, etc.) which is at least partially light-transmissive to the wavelength to be emitted or detected, and more preferably transparent, for the wavelength to be emitted or detected. Preferably, the material includes from about 10% to about 95% by weight semiconductor nanocrystals. Such dispersion can be deposited as a full or partial layer or in a patterned arrangement by any of the above-listed or other known techniques. Examples of other suitable materials include, for example, polystyrene, epoxy, polyimides, and silica glass. Other host materials may be determined to be useful or desirable. Preferably such dispersions are deposited by solution process technology. After application to the surface, such material desirably contains dispersed semiconductor nanocrystals where the nanocrystals have been selected and arranged by composition, structure, and/or size so as to absorb the light to be detected and to generate an electrical signal or other output in response to the absorbed light. Dispersions of semiconductor nanocrystals in, e.g., polystyrene or epoxy, can be prepared as set forth, for example, in U.S. Pat. No. 6,501,091 or by other suitable techniques.

Semiconductor nanocrystals can be deposited at a micron-scale (e.g., less than 1 mm, less than 500 μm, less than 200 μm, less than 100 μm or less, less than 50 μm or less, less than 20 μm or less, less than 10 μm or less) or larger patterning of features on a surface. In certain embodiments, the features have a size in the range from about 10 to about 100 micron. In certain embodiments the features can a size of about 30 microns. Features in the size range from about 10 to about 100 microns are preferred sizes for subpixels features. The surface can have dimensions of 1 cm or greater, 10 cm or greater, 100 cm or greater, or 1,000 cm or greater. Optionally, devices can be stitched (or tiled) together, to expand device sizes from 12″ squares, to ‘n×12″ squares, as is frequently done in the semiconductor lithography field.

In certain embodiments, two or more different semiconductor nanocrystals (e.g., having different compositions, structures, and/or sizes) can be included. A device including semiconductor nanocrystals of different compositions, sizes, and/or structures can emit or absorb electromagnetic radiation at the wavelengths or wavelength bands characteristic of each of the different compositions. The particular wavelength(s) to be emitted or absorbed and detected can be controlled by selecting appropriate combinations of semiconductor nanocrystal compositions, structures, and/or sizes as well as the output to be generated.

In certain embodiments, one or more populations of different semiconductor nanocrystals, each having predetermined emission or absorption characteristics, can be deposited in a predetermined arrangement. The predetermined absorption characteristics of each population can be the same or different from each of any other population included. Patterned semiconductor nanocrystals can be used to form an array of devices (or pixels) comprising, e.g., red, green, and blue, or alternatively, red, orange, yellow, green, blue-green, blue, violet, or other visible, infrared, or ultraviolet emitting or absorbing, or other combinations of distinguishable wavelength, based on the intended use of the device. In a photodetector device, preferably, the electrical response generated can also be indicative of the intensity or relative intensity of the absorbed radiation.

Each layer of the device can be deposited as a blanket film. In certain embodiments, this permits simple on-silicon integration.

Any one or more of the layers can be patterned.

In certain embodiments, the device is made in a controlled (oxygen-free and moisture-free) environment.

The surface of the device opposite the substrate may optionally be completed by encapsulation with one or more layers of, e.g., polymer, glass, ceramic, and/or metal. When more than one layer is used, the layers may be the same or different materials.

Optionally, the viewing surface of the device can be anti-reflective e.g., by use of antireflective coating(s) or a polarizing filter, e.g., a circular polarizer.

Electrical connections for connecting the device to a power supply can also be included.

A device can optionally further include optics or an optical system to enhance viewability of the device output. Examples of preferred optics for use, for example, can include lenses. For a photodetector device with infrared detection, sapphire or germanium lenses can be preferred.

Because of the diversity of available semiconductor nanocrystal materials, and the wavelength tuning via semiconductor nanocrystal composition and diameter or size, photodetector devices including semiconductor nanocrystals can have any predetermined wavelength sensitivity, e.g., from UV to MIR.

Examples of a photodetector including semiconductor nanocrystals are described in “A Quantum Dot Heterojunction Photodetector” by Alexi Cosmos Arango, Submitted to the Department of Electrical Engineering and Computer Science, in partial fulfillment of the requirements for the degree of Masters of Science in Computer Science and Engineering at the Massachusetts Institute of Technology, February 2005, the disclosure of which is hereby incorporated herein by reference in its entirety.

Other examples of photodetectors and/or uses thereof are described in Qi, et al., “Efficient Polymer Nanocrystal Quantum-Dot Photodetectors”, Appl. Phys. Lett. 86 093103 (2005); Hegg, et al., A Nano-scale Quantum Dot Photodetector by Self-Assembly, Proceedings of the SPIE, Volume 6003, pp. 10-18 (2005); and Rogalski, “Optical Detectors for Focal Plane Arrays”, Opto-Electronics Review 12(2) 221-245 (2004). The disclosures of the foregoing publications are hereby incorporated herein by reference in their entirety.

As mentioned above, a device comprising a photodetector device can further include optics for receiving the light to be absorbed.

A device can include filter means for selectively filtering the light emitted or received by the semiconductors nanocrystals included in the device.

A device comprising a photodetector device can also include electronic means that record the electrical output of each photodetector.

The present invention will be further clarified by the following non-limiting example(s), which are intended to be exemplary of the present invention.

### EXAMPLES

### Semiconductor Nanocrystal Materials & Device Fabrication Methods

### Synthesis of PbS Nanocrystals

The synthesis of PbS nanocrystals is based on the work by Hines, et al. Adv. Mater., 15, 1844 (2003). The precursors used are lead oxide and bis(trimethylsilyl)sulfide in a molar ratio of 2:1 with varying concentrations of oleic acid. Higher concentrations of oleic acid results in larger PbS nanoparticles. Absorption of PbS particles can be tuned from 800 to 1700 nm.

### Ligand Exchange of PbS Nanocrystals

Oleic acid, the capping ligand on the surface of the PbS semiconductor nanocrystals, is exchanged with different amines (e.g., n-butylamine, n-octylamine) to modify the alkyl-chain length of the ligands following the procedure described by Konstantatos, et al., Nature, 2006, 44(13), 180-183. The semiconductor nanocrystals are dissolved in amine at a concentration of 100 mg/ml, and left for 3 days under an inert environment. The semiconductor nanocrystals are then precipitated with isopropanol and redispersed in hexane under inert conditions. (A semiconductor nanocrsytals may also be referred to herein as a “nanocrystal” or a “QD”.)

### Device Fabrication Summary

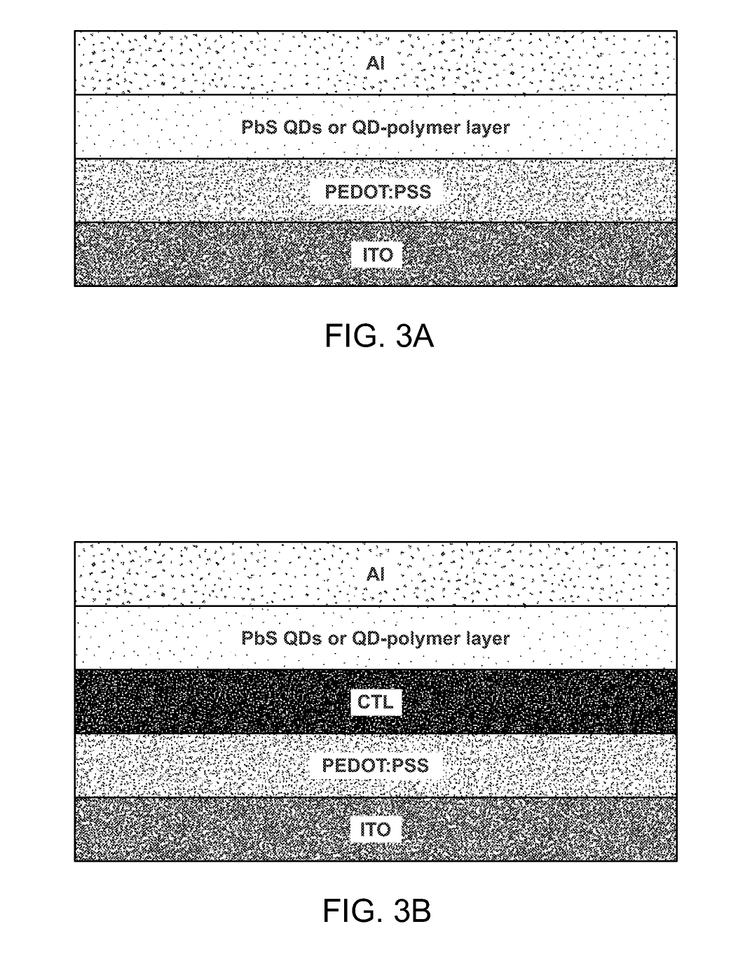

FIG. 3 schematically depicts examples of two device structures, a single layer structure (FIG. 3(a)) and a heterojunction structure (FIG. 3(b)), described below. Generally, for the photodetector devices described in the examples, a 70 nm thick conductive polymer, poly-3,4-ethylenedioxythiophene doped with polystyrene sulfonate (PEDOT:PSS), is deposited by spin coating onto the ITO electrode, The PEDOT:PSS film is cured at 125° C. for 1 hour in a nitrogen environment. For single layer structures (see FIG. 3(a)), solutions of PbS QDs in hexane solvent or PbS QD-polymer blends in toluene solvent are spin cast at 1000 rpm for 1 minute in a glove box, in which the oxygen and water level are each generally below 1 ppm. In parallel with device fabrication, reference PbS QD films are also fabricated by spin-coating PbS QD solution on cleaned glass slides to measure the film thickness and photo absorption at the first excitonic peak.

In general, the devices described in the examples include PbS QDs that are either cap—(or ligand—) exchanged in solution or in solid state by immersion of the film sample. Control devices utilizing the native oleic acid ligands have extremely high resistance and no observable photo current. For solid-state cap-exchange, devices are soaked into 0.1 M n-butylamine in acetonitrile or sodium hydroxide solution for 10 minutes, followed by oven-bake at 70° C. for 1 hour in a glove box to remove excess solvent. Heterojunction devices with polymer CTLs are not successfully cap-exchanged in solid-state as the polymer CTL degrades in the process.

After chemical treatment, a 100 nm Al electrode is evaporated through a shadow mask in a vacuum chamber at a pressure of <10⁻⁷ Torr. The final device pixel area is 3 mm×3 mm. The devices are then packaged in a nitrogen glove box with glass coverslips and UV curable epoxy to minimize device exposure to oxygen and humidity.

### Heterojunction Device Fabrication.

An example of a heterojunction QD device structure is shown in FIG. 3(b). All the fabrication procedures in the following examples are similar to the previous description for single layer photodetector devices except for the inclusion of a charge transport layer in accordance with the invention or a polymeric charge transport layer. (A charge transport layer is marked “CTL” in FIG. 3(b).)

For formation of a charge transport layer in accordance with the invention in the following examples, a metal layer is evaporated directly onto the PEDOT:PSS coated ITO glass (before spin-coating the quantum dots) and baked at 100° C. in air for about three hours to form a metal oxide at least on the surface of the metal layer opposite the PEDOT:PSS coated ITO glass. (Depending on the particular metal and the oxidation conditions, the entire metal layer may be oxidized.) The final thickness of the metal oxide layer formed is approximately 30 nm. After the metal oxide is formed, the substrate is brought into the glove box to spin coat PbS QDs and then soaked in n-butylamine solution as described above.

For comparative purposes, devices including polymeric CTLs are prepared wherein the polymeric CTL is simply deposited by spin coating. The function of either the polymer or metal oxide used in the device design is to improve exciton dissociation.

Butylamine capping PbS film morphology

Butylamine film soaking can improve the charge transport mobility by decreasing the interparticle spacing, but roughens the surface of the QD film. Numerous micro-cracks and pinholes can be created by chemical treatment. The partial current leakage (on the order of microampere at several voltage of bias) in the device is a common problem and contributes to the breakdown of the device at higher bias.

The butylamine ligand exchange in solution process can improve the quality of quantum dot film formation. The surface of the dot film made by butylamine ligand exchange treatment in solution is much smoother than the dot film with butylamine soaking treatment. As expected, the photoconductivity of the post-treatment films was enhanced by shrinking the interdot spacing.

Heterojunction device with polymeric CTL

Utilizing polymers as charge transport materials in hybrid QD photodetector is well-known. MEH-PPV has higher hole mobility than electron mobility and quantum dots have less hole mobility than electron mobility. The device(s) described in the examples that include a polymeric CTL includes MEH-PPV as the CTL. For this hybrid structure, butylamine capped dots are spin-coated on the MEH-PPV polymer layer to form the heterojunction structure.

### Heterojunction Structure Including a Charge Transport Layer Comprising an Oxidized Layer of Bismuth Metal

The heterojunction structure ITO-Oxidized Metal Layer-PbS QD-hole transport layer-Al of the examples included a thermally evaporated layer of bismuth that is subsequently oxidized by heating in a furnace at a temperature of about 300° C. under ambient conditions for 3 hours to form a homogeneous bismuth oxide film.

The function of metal oxide here is three-fold. First, it is used as a charge transport layer. It is worth mentioning that the vacuum-referenced band edge of the metal oxide is uncertain, but it is possible that a dipole layer could be formed at the interface between metal oxide and quantum dots, altering the effective band alignment and the nanocrystal energy levels vary with size. Second, the metal oxide allows for exciton dissociation at the hetedunction, increasing device efficiencies. Third, metal oxides can be an important choice for the device structure because they can be resistant to chemical treatments, e.g., the soaking treatments described above, unlike conventional polymeric charge transport materials, and are compatible with the other solution-process bases fabrication methods that may be used. Other metals with similar energy levels to bismuth can also be used.

Heterojunction photodetector structures with solid-state cap-exchanged QDs and a charge transport layer including metal oxide prepared in accordance with the invention can demonstrate higher internal quantum efficiency (IQE), low dark current and better stability than a single layer device or a heterojunction device including a polymeric MEH-PPV charge transport layer, in each case that include solid-state cap-exchanged QDs.

Inclusion of bismuth oxide as charge transport material with a cathode comprising ITO can provide good energy level alignment of the conduction band of bismuth oxide with the work function of ITO. In such case, the electron can be easily separated from an exciton formed on QD layer and then transferred from metal oxide CTL and harvested by electrode.

Other techniques, methods, and applications that may be useful with the present invention are described in International Publication No. WO 2009/123763 of QD Vision, Inc. for “ ”Light-Emitting Device Including Quantum Dots”, published 8 Oct. 2009, International Application No. PCT/US2010/51867 of QD Vision, Inc. for “Device Including Quantum Dots”, filed 7 Oct. 2010; International Application No. PCT/US2010/56397, for “Device Including Quantum Dots”, filed 11 Nov. 2010, and International Publication No. WO 2007/112088 of QD Vision, Inc. for “Hyperspectral Imaging Device”, published 4 Oct. 2007. The disclosures of each of the foregoing listed patent applications are hereby incorporated herein by reference in their entireties.

As used herein, “top” and “bottom” are relative positional terms, based upon a location from a reference point. More particularly, “top” means furthest away from the substrate, while “bottom” means closest to the substrate. For example, the bottom electrode is the electrode closest to the substrate, and is generally the first electrode fabricated; the top electrode is the electrode that is more remote from the substrate, on the top side of the semiconductor nanociystals. The bottom electrode has two surfaces, a bottom surface closest to the substrate, and a top surface further away from the substrate. Where, e.g., a first layer is described as disposed or deposited “over” a second layer, the first layer is disposed further away from substrate. There may be other layers between the first and second layer, unless it is otherwise specified. For example, a cathode may be described as “disposed over” an anode, even though there are various other layers in between.

All the patents and publications mentioned above and throughout are incorporated in their entirety by reference herein.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

1. A method of making a device comprising semiconductor nanocrystals, the method comprising disposing a first layer capable of transporting charge comprising a metal layer over a first electrode, oxidizing at least the surface of the metal layer opposite the first electrode, disposing a layer comprising semiconductor nanocrystals over the oxidized metal surface, and disposing a second electrode over the layer comprising semiconductor nanocrsytals.

2. A method in accordance with claim 1 wherein at least a portion of the semiconductor nanocrystals are engineered to generate an electrical output in response to absorption of light having a wavelength to be detected.

3. A method in accordance with claim 1 wherein at least a portion of the semiconductor nanocrystals are engineered to emit light having a predetermined peak emission wavelength in response to optical or electrical excitation.

4. A method in accordance with claim 1 wherein the semiconductor nanocrystals are disposed as a layer.

5. A method in accordance with claim 1 further comprising disposing a second layer comprising a material capable of transporting charge between the layer comprising semiconductor nanocrsytals and disposing the second electrode over the second layer comprising a material capable of transporting charge.

6. A method in accordance with claim 1 wherein the metal layer comprises an oxidizable metal.

7. A device comprising a layer comprising semiconductor nanocrystals disposed between a first electrode and a second electrode, and a first layer capable of transporting charge disposed between the layer comprising semiconductor nanocrystals and one of the electrodes, wherein the first layer capable of transporting charge comprises a metal layer wherein at least the surface of the metal layer facing the layer comprising semiconductor nanocrystals is oxidized.

8. A device in accordance with claim 7 wherein at least a portion of the semiconductor nanocrystals are engineered to generate an electrical output in response to absorption of light having a wavelength to be detected.

9. A device in accordance with claim 7 wherein at least a portion of the semiconductor nanocrystals are engineered to emit light having a predetermined peak emission wavelength in response to optical or electrical excitation.

10. A device in accordance with claim 7 wherein the semiconductor nanocrystals are disposed as a layer.

11. A device in accordance with claim 7 further comprising a second layer comprising a material capable of transporting charge between the layer comprising semiconductor nanocrsytals and the other of the electrodes.

12. A device in accordance with claim 7 wherein the metal layer comprises an oxidizable metal.

13. A device in accordance with claim 7 wherein the metal layer is oxidized in situ prior to disposing the layer comprising semiconductor nanocrystals over the oxidized surface.

14. A device in accordance with claim 7 wherein the device comprises a photodetector.

15. A device in accordance with claim 7 wherein the device comprises a light emitting device.

16. A device in accordance with claim 7 wherein the semiconductor nanocrystals comprise PbS and the metal layer comprises bismuth.

17. A method in accordance with claim 1 wherein the device comprises a photodetector.

18. A method in accordance with claim 1 wherein the device comprises a light emitting device.

19. A method in accordance with claim 1 wherein the semiconductor nanociystals comprise PbS and the metal layer comprises bismuth.

20. (canceled)

21. (canceled)
